(19) United States
(12) Patent Application Publication
(10) Pub. No.: US 2015/0013901 A1
(43) Pub. Date: Jan. 15, 2015

(54) MATRIX DEFINED ELECTRICAL CIRCUIT STRUCTURE

(71) Applicant: HSIO TECHNOLOGIES, LLC, Maple Grove, MN (US)

(72) Inventor: JAMES RATHBURN, Maple Grove, MN (US)

(73) Assignee: HSIO TECHNOLOGIES, LLC

(21) Appl. No.: 14/327,916

(22) Filed: Jul. 10, 2014

Related U.S. Application Data
(60) Provisional application No. 61/845,076, filed on Jul. 11, 2013.

(51) Int. Cl. H05K 3/46; H05K 3/12; H01L 21/768; H05K 3/18

(52) U.S. Cl. CPC H05K 3/4611; H05K 3/181; H05K 3/188; H05K 3/12; H01L 21/76877
USPC 156/277; 427/98.4; 438/666; 205/126

(57) ABSTRACT

A system and method for “pixelating” a three-dimensional circuit structure into a three-dimensional matrix of cubes that are located with respect to a coordinate system. The design step is typically performed on a conventional computer using computer aided design software that pixelates the proposed circuit structure into an array of uniformly sized cube. The fabrication process involves adding and subtracting bulk materials from the individual cubic positions within the pixelated representation of the circuit structure. Various existing and new techniques can be used to add or subtract bulk materials as the cubic positions within the matrix to construct the circuit structure.

### CROSS-REFERENCE TO RELATED APPLICATIONS

This application claims the benefit of U.S. Provisional Application No. 61/845,076, filed Jul. 11, 2013, the disclosure of which is hereby incorporated by reference.

### TECHNICAL FIELD

The present disclosure relates to a system and method for designing and fabricating circuit structures by adding and subtracting bulk materials from individual cubic units within a pixelated representation of the circuit structure. The present disclosure leverages processes used in the printed circuit and semiconductor packaging industries to provide a high performance electrical interconnect between two or more components in an electrical system.

### BACKGROUND OF THE INVENTION

Traditional printed circuits are often constructed in what is commonly called rigid or flexible formats. The rigid versions are used in nearly every electronic system, where the printed circuit board (PCB) is essentially a laminate of materials and circuits that when built is relatively stiff or rigid and cannot be bent significantly without damage.

Flexible circuits have become very popular in many applications where the ability to bend the circuit to connect one member of a system to another has some benefit. These flexible circuits are made in a very similar fashion as rigid PCB's, where layers of circuitry and dielectric materials are laminated. The main difference is the material set used for construction. Typical flexible circuits start with a polymer film that is clad, laminated, or deposited with copper. A photolithography image with the desired circuitry geometry is printed onto the copper, and the polymer film is etched to remove the unwanted copper. Flexible circuits are very commonly used in many electronic systems such as notebook computers, medical devices, displays, handheld devices, autos, aircraft and many others.

Flexible circuits are processed similar to that of rigid PCB's with a series of imaging, masking, drilling, via creation, plating, and trimming steps. The resulting circuit can be bent, without damaging the copper circuitry. Flexible circuits are solderable, and can have devices attached to provide some desired function. The materials used to make flexible circuits can be used in high frequency applications where the material set and design features can often provide better electrical performance than a comparable rigid circuit.

Flexible circuits are connected to electrical system in a variety of ways. In most cases, a portion of the circuitry is exposed to create a connection point. Once exposed, the circuitry can be connected to another circuit or component by soldering, conductive adhesive, thermosonic welding, pressure or a mechanical connector. In general, the terminals are located on an end of the flexible circuit, where edge traces are exposed or in some cases an area array of terminals are exposed. Often there is some sort of mechanical enhancement at or near the connection to prevent the joints from being disconnected during use or flexure.

In general, flexible circuits fill a needed function within the electronics industry. They can be considered expensive compared to some rigid PCB products. They do have some limitations regarding layer count or feature registration, and they are generally used for small or elongated applications. Rigid PCB's and package substrates experience challenges as the feature sizes and line spacing are reduced to achieve further miniaturization and increased circuit density.

The use of laser ablation has become increasingly used to create the via structures for fine line or fine pitch structures. The use of lasers allows localized structure creation, where the processed circuits are plated together to create via connections from one layer to another. As density increases, the laser processed via structures can experience significant taper, carbon contamination, layer to layer shorting during the plating process due to registration issues, and high resistance interconnections that may be prone to result in reliability issues. The challenge of making fine line PCBs often relates to the difficulty in creating very small or blind and buried vias.

### BRIEF SUMMARY OF THE INVENTION

The present disclosure is directed to a system and method for “pixelating” a three-dimensional circuit structure into a three-dimensional matrix of cubes that are located with respect to a coordinate system. The present system and method can be used to both design and fabricate the circuit structures. The design step is typically performed on a conventional computer using computer aided design software that pixelates the proposed circuit structure into an array of uniformly sized cube. The fabrication process involves adding and removing bulk materials from the individual cubic positions within the pixelated representation of the circuit structure. Various existing and new techniques can be used to add or subtract bulk materials as the cubic positions within the matrix to construct the circuit structure.

In one embodiment the cubic positions are about 20 microns on each side, although any size cube can be used. The size of the cubes can preferably be rescaled to a different size to increase or decrease the resolution of the matrix.

An algorithmic principle is preferably used to define the bulk material located at each cubic position within the matrix during each step of the process. In one embodiment, a design automation formulae is created that specifies the material type for each cubic position during each step of the process, such as for example, (x, y, z, material, step number).

The present disclosure includes depositing one material type during a particular step of the process, and then removing that material in a subsequent step and/or replacing that material with a different material type. For example, a particular cubic position may be designated to be occupied by a solder mask during a particular step of the fabrication process—(0, 1, 1, solder mask, step 1). This solder mask may be removed during a subsequent step of the process—(0, 1, 1, air, step 2). In yet another step another material, such as a ferro-magnetic material, a conductor, a semiconductor, or a dielectric material is located at that position—(0, 1, 1, copper, step 3).

In one embodiment, the matrix defines a volume or form factor with maximum outside dimensions that constrains the size of the circuit structure. In an alternate embodiment, a matrix can be superimposed on an existing circuit structure design. This alternate embodiment may result in a single position containing two different materials. As a result, the algorithm for the present process selects the appropriate material based on a predetermined criteria.

The printed circuit can be produced to replicate a traditional circuit or interconnects between one or more members of a system. The present system permits circuit structures to be produced digitally, without tooling or costly artwork. The circuit structures can be produced as a “Green” product, with dramatic reductions in environmental issues related to the production of conventional flexible circuits.

The present disclosure is directed to a method of making a circuit structure including the steps of creating a first three dimensional matrix divided into a plurality of uniformly sized cubic positions. A series of steps are defined for making a first circuit structure including for each cubic position at least position data locating the cubic position within the first three dimensional matrix and a material for each cubic position. At the designated cubic positions within the first matrix a first dielectric layer is deposited. The first dielectric layer includes a plurality of cubic positions with recesses corresponding to a target circuit geometry. A conductive material is deposited in at least a portion of the cubic positions corresponding to the recesses to form a circuit geometric comprising a plurality of conductive traces. At designated cubic positions within the first matrix a second dielectric layer extends over at least a portion of the cubic positions containing the conductive material.

The present disclosure is also directed to a method of using a general purpose computer to design a circuit structure. An operator creates in a computer a first three dimensional matrix divided into a plurality of uniformly sized cubic positions. The operator designates a particular material to be located in each cubic position in the three dimensional matrix during each step of the fabrication process. During some of the early steps, many of the cubic positions may be empty. Also, the particular material in a particular cubic position may also change from step-to-step.

This disclosure enables the production of very small low resistance vias to increase density and reduce line and feature pitch of the circuits as well as a host of electrical enhancements that provide an electrical interconnect that may prove to be superior to the traditional methods. In basic terms, the structure leverages methods used in the semiconductor packaging industry such as pillar termination to act as the via connecting layers within the circuit stack. In addition, the PCB can be treated as a system of its' own by incorporating printed transistors or other passive and active function.

The present system can be used to construct rigid or flexible circuit structure. At least one electrical device is optionally printed on a dielectric layer or the polymeric film and electrically coupled to at least a portion of the circuit geometry. Optical quality materials can be printed or deposited in at least a portion of the recesses to form optical circuit geometries. Electrical devices, such as for example, ground planes, power planes, transistors, capacitors, resistors, RF antennae, shielding, filters, signal or power altering and enhancing devices, memory devices, embedded IC, and the like, can be printed on the circuit structure.

Contact members can be printed in a variety of shapes and sizes, depending on the terminal structure on the circuit members. The contact members can be positioned at a variety of locations, heights, or spacing to match the parameters of existing connections, allowing replacement of existing interconnect connectors, without changing hardware or the PCB. In some embodiments, the tips of the contact members are treated with specialty materials to increase long term reliability, such as for a test socket application.

The use of additive printing processes permits the material set in a given layer to vary. Traditional PCB and flex circuit fabrication methods take sheets of material and stack them up, laminate, and/or drill. The materials in each layer are limited to the materials in a particular sheet. Additive printing technologies permit a wide variety of materials to be applied on a layer with a registration relative to the features of the previous layer. Selective addition of conductive, non-conductive, or semi-conductive materials at precise locations to create a desired effect has the major advantages in tuning impedance or adding electrical function on a given layer. Tuning performance on a layer by layer basis relative to the previous layer greatly enhances electrical performance.

Since the individual contact members are preferably printed, the present circuit structure can be removed and replaced without having to handle or assemble individual contact members. The circuit members on the circuit structure can be configured to mate with existing or custom connectors in a LIF, ZIF, or plugged connector configuration, while maintaining or improving signal integrity.

Vias can be printed on the compliant printed flexible circuit to electrically couple adjacent layers of the circuit geometry. One or more contact members electrically coupled to at least a portion of the circuit geometry are printed to extend above the dielectric covering layer. The compliant printed flexible circuit is optionally singulated adjacent at least one of the contact members.

The present disclosure is also directed to several additive processes that combine the mechanical or structural properties of a polymer material, while adding metal materials in an unconventional fashion, to create electrical paths that are refined to provide electrical performance improvements. By adding or arranging metallic particles, conductive inks, plating, or portions of traditional alloys, the compliant printed flexible circuit reduces parasitic electrical effects and impedance mismatch, potentially increasing the current carrying capacity.

The printing process permits the fabrication of functional structures, such as conductive paths and electrical devices, without the use of masks or resists. Features down to about 10 microns can be directly written in a wide variety of functional inks, including metals, ceramics, polymers and adhesives, on virtually any substrate—silicon, glass, polymers, metals and ceramics. The substrates can be planar and non-planar surfaces. The printing process is typically followed by a thermal treatment, such as in a furnace or with a laser, to achieve dense functionalized structures.

The compliant printed flexible circuit can be configured with conductive traces that reduce or redistribute the terminal pitch, without the addition of an interposer or daughter substrate. Grounding schemes, shielding, electrical devices, and power planes can be added to the interconnect assembly, reducing the number of connections to the PCB and relieving routing constraints while increasing performance.

### BRIEF DESCRIPTION OF THE SEVERAL VIEWS OF THE DRAWING

FIG. 1 is a perspective view of a three-dimensional matrix used to construct circuit structures in accordance with an embodiment of the present disclosure.

FIG. 2A is a sectional view of a circuit structure constructed using in accordance with an embodiment of the present disclosure.

FIG. 2B is a plan view of the circuit structure of FIG. 2A.

FIG. 3A is a sectional view of a circuit structure constructed using in accordance with an embodiment of the present disclosure.

FIG. 3B is a plan view of the circuit structure of FIG. 3A.

FIG. 4 is a side-sectional view of a method of making a high density circuit structure in accordance with an embodiment of the present disclosure.

FIG. 5 is a side-sectional view of the high density circuit structure of FIG. 4 with a full metal via in accordance with an embodiment of the present disclosure.

FIG. 6 is a side-sectional view of a discrete layer to be added to the high density circuit structure of FIG. 5 in accordance with an embodiment of the present disclosure.

FIG. 7 is a side-sectional view of the discrete layer of FIG. 6 fused to the high density circuit structure in accordance with an embodiment of the present disclosure.

FIG. 8 is a side-sectional view of a circuitry layer added to the high density circuit structure of FIG. 7 in accordance with an embodiment of the present disclosure.

FIG. 9 is a side-sectional view of a dielectric layer added to the high density circuit structure of FIG. 8 in accordance with an embodiment of the present disclosure.

FIG. 10 is a side-sectional view of a modification to the circuitry layer of FIG. 10 in accordance with an embodiment of the present disclosure.

FIG. 11 illustrates an electrical interconnect interfaced with a BGA device in accordance with an embodiment of the present disclosure.

FIG. 12 illustrates an electrical interconnect for a flexible circuit in accordance with an embodiment of the present disclosure.

FIG. 13 illustrates an electrical interconnect for an IC package in accordance with an embodiment of the present disclosure.

FIG. 14 illustrates an alternate electrical circuit for an IC package in accordance with an embodiment of the present disclosure.

FIG. 15 is a side sectional view of an electrical circuit in accordance with an embodiment of the present disclosure.

FIG. 16 is a side sectional view of an alternate electrical circuit with printed compliant material in accordance with an embodiment of the present disclosure.

FIG. 17 illustrates an electrical circuit with optical features in accordance with an embodiment of the present disclosure.

FIG. 18 illustrates an alternate high density electrical circuit with optical features in accordance with an embodiment of the present disclosure.

FIG. 19 illustrates an alternate high density circuit structure with printed vias in accordance with an embodiment of the present disclosure.

FIG. 20 illustrates an alternate high density circuit structure with printed electrical devices in accordance with an embodiment of the present disclosure.

FIG. 21 illustrates an alternate high density electrical circuit with printed compliant electrical pads to plug into another connector in accordance with an embodiment of the present disclosure.

FIG. 22 is a flow chart of a method of using a general purpose computer to design a circuit structure in accordance with an embodiment of the present disclosure.

### DETAILED DESCRIPTION OF THE INVENTION

The present disclosure is directed to a system for “pixelating” a three-dimensional circuit structure into a three-dimensional matrix of cubes that are located with respect to a coordinate system. The present system and method can be used to both design and fabricate the circuit structures. The fabrication process involves adding and removing bulk materials from the individual cubic units within the pixelated representation of the circuit structure.

Various existing and new techniques are used to add or subtract bulk materials as the cubic positions within the matrix to construct the circuit structure, including U.S. Ser. No. 13/413,724, entitled Copper Pillar Full Metal Via Electrical Circuit Structure filed Mar. 7, 2012; U.S. Ser. No. 13/410,943 entitled Area Array Semiconductor Device Package Interconnect Structure with Optional Package-to-Package or Flexible Circuit to Package Connection, filed Mar. 2, 2012; U.S. Ser. No. 13/700,639 entitled Electrical Connector Insulator Housing, filed Nov. 28, 2012; and PCT/US2013/030856 entitled Hybrid Printed Circuit Assembly with Low Density Main Core and Embedded High density Circuit Regions, filed Mar. 13, 2013; all of which are hereby incorporated by reference.

The process for constructing a circuit structure typically involves multiple steps. As such, the present system encompasses adding a material to a particular cubic position in one step and then removing and/or replacing that material in a subsequent step.

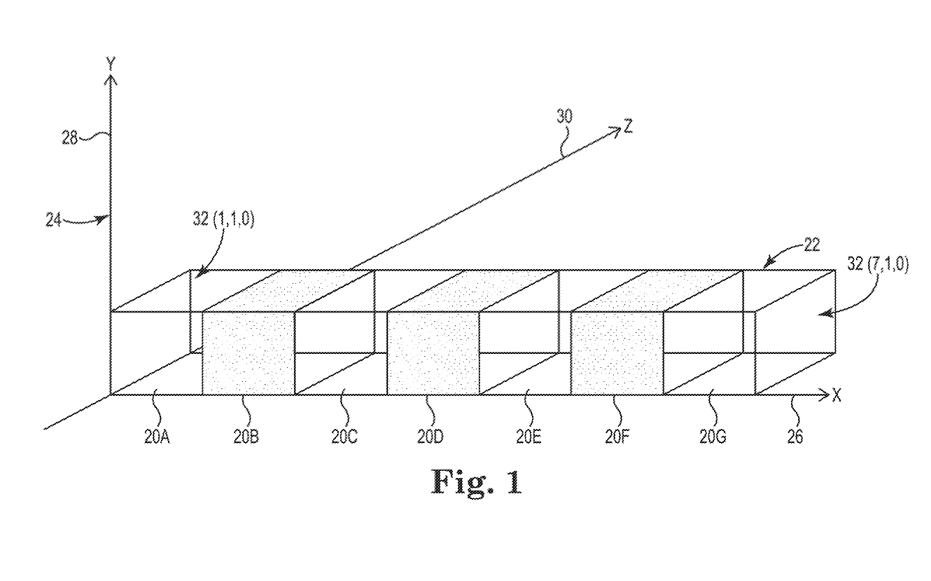

FIG. 1 illustrates a series of cubes 20A-20G (collectively “20”) in a linear array or matrix 22 in relation to a coordinate system 24. In the illustrated embodiment, the coordinate system 24 is a conventional Cartesian coordinate system with an X-axis 26, a Y-axis 28, and a Z-axis 30. Each cube 20 has a designated position 32 with respect to the coordinate system 24 using conventional Cartesian coordinates (X, Y, Z). For example, cube 20A is located at position (1, 1, 0) and cube 20G is located at position (7, 1, 0), also referred to as a cubic position. In the illustrated embodiment, each cube 20 has a size of about 20 microns on each side, although any size cube 20 can be used. In one embodiment, the size of the cubes 20 can be rescaled to a different size do increase or decrease the resolution of the matrix 22.

An algorithmic principle is preferably used to define the bulk material located at each position 32 within the matrix 22 during each step of the process. In one embodiment, a design automation formulae is created that specifies the material type for each position 32 during each step of the process, such as for example, (x, y, z, material, step number).

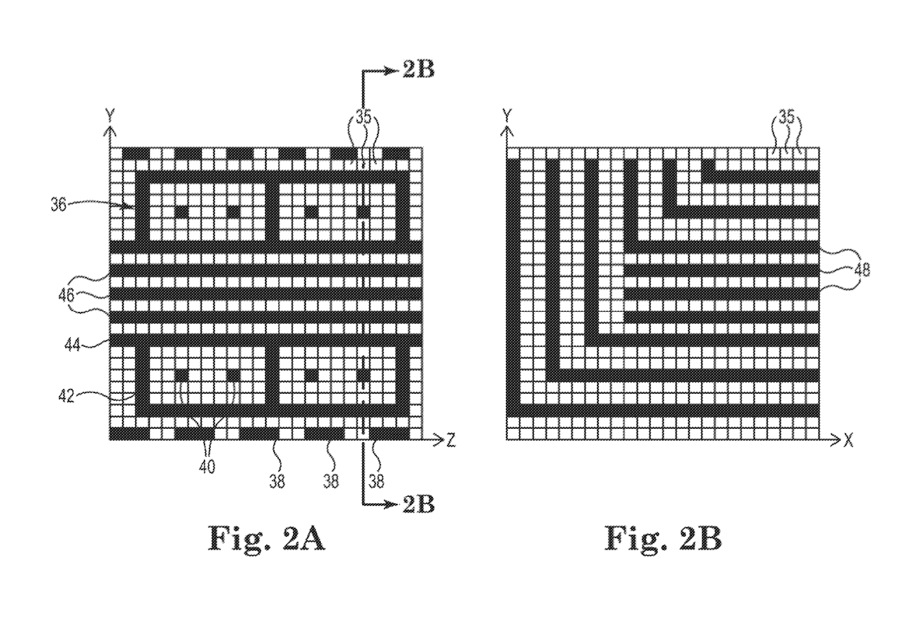

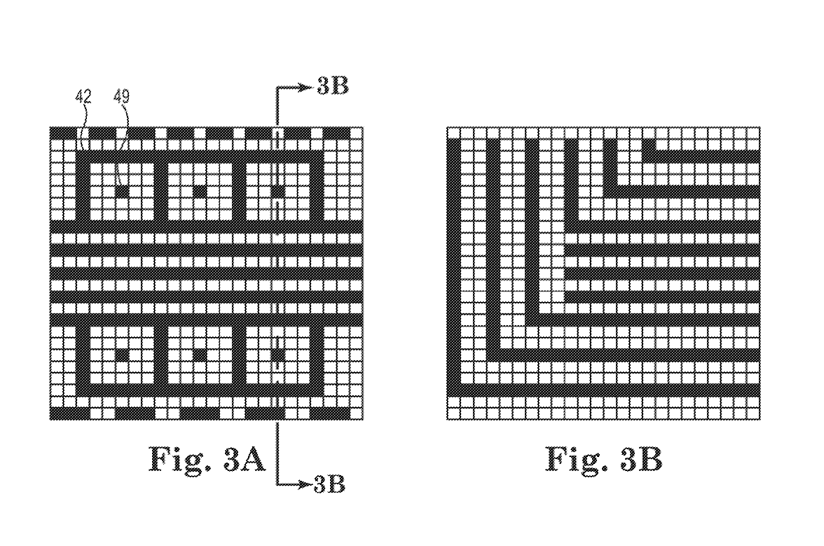

In the embodiment of FIG. 1, position (1, 1, 0) is a dielectric material and position (2, 1, 0) is copper. Each position 32 is populated to define a specific material type such that the resultant overall assembly of the matrix 22 creates the final circuit structure. (See e.g., FIGS. 2A through 3B).

The principle can also be expanded to consider process steps where one material type can be deposited during one step and removed in a subsequent step and/or replaced by another material type. For example, a particular position 32 may be designated to be occupied by a solder mask during a particular step of the fabrication process (e.g., (0, 1, 1, solder mask, step 1)). This solder mask may be removed during a subsequent step of the process (e.g., (0, 1, 1, air, step 2)). In yet another step, another material, such as a ferro-magnetic material, a conductor, a semiconductor, or a dielectric material is located at that position (e.g., (0, 1, 1, copper, step 3)).

In one embodiment, the matrix 22 defines a volume or form factor with maximum outside dimensions that constrains the size of the circuit structure. During the design process, the limits of the coordinate system constrain the circuit structure within the desired envelope.

In an alternate embodiment, a matrix 22 is superimposed on an existing circuit structure. This alternate embodiment may result in a single position 32 containing two different materials. As a result, the algorithm for the present process must select the appropriate material based on predetermined criteria. For example, where more than one material is located in a particular cubic position, the algorithm selects the material that constitutes more than 50% of the total volume of that cube.

In connection with those circuit structures, various techniques are disclosed for adding or subtracting bulk materials from a particular cubic location within the matrix. These techniques are for example only and do not in any way limit the broad scope of the present pixelated circuit design and production system and method.

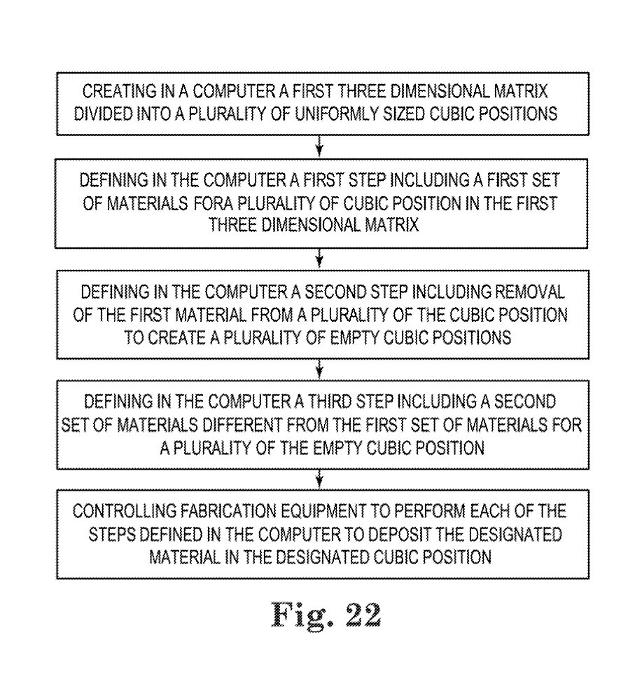

FIG. 22 is a flow chart summarizing a method of using a general purpose computer to design a circuit structure in accordance with an embodiment of the present disclosure. An operator creates in a computer a first three dimensional matrix divided into a plurality of uniformly sized cubic positions. Computer aided design software loaded on the computer is used by the operator to designate a particular material to be located in each cubic position in the three dimensional matrix during each step of the fabrication process. During some of the early steps, many of the cubic positions may be empty. As discussed above, the particular material in a particular cubic position may also change from step-to-step.

In a first step, the operator defines in the computer a first set of materials for a plurality of cubic position in the first three dimensional matrix. In a second step, the operator defines in the computer removal of the first set of materials from a plurality of the cubic position to create a plurality of empty cubic positions. In a third step, the operator defines in a computer a second set of materials different from the first material for a plurality of the empty cubic position. The steps summarized in FIG. 22 correspond to processing steps to fabricate a circuit structure as designed in the computer. The computer can also be used to control fabrication equipment to perform each of the steps to fabricate the actual circuit structure. That is, the computer controls addition or removal of the designated material from the designated cubic position for each step of the fabrication process.

What follows are a series of circuit structures constructed in accordance with the system and method of the present disclosure. Each of the illustrated circuit structures can be considered either a design document showing the desired bulk materials at the cubic positions during various steps of the fabrication process or the actual circuit structure being fabricated in accordance with an embodiment of the present disclosure.

FIGS. 2A and 2B illustrate a circuit structure 36 designed and fabricated using a system in accordance with an embodiment of the present disclosure. The images of FIGS. 2A and 2B can be considered either a design lay-out, as an operator might view on a computer screen, or the actual circuit structure 36 constructed using the present system and method.

FIG. 2A is an array of twenty four cubic positions 35 along the Y-axis and twenty five cubic positions along the Z-axis. FIG. 2B is an array of twenty four cubic positions 35 along the X-axis and twenty five cubic positions along the Y-axis.

FIG. 2A illustrates a series of surface mount pads 38 are located along the first row (Y=1) of the array. For example, the first surface mount pad 38 is designated (0, 1, 1-3, copper). Twin axial circuits 40 are formed at positions (0, 6, 6) and (0, 6, 10). The twin axial circuits 40 are surrounded by ground traces 42. The ground traces 42 are coupled to ground traces 44 formed in row Y=9. Conductive traces 46 providing power are formed in rows Y=11, 13, 15. FIG. 2B illustrates a series of conductive traces 48 constructed in positions corresponding to a plurality of cubic positions 35.

FIGS. 3A and 3B are sectional views of a circuit structure having co-axial structures 49 surrounded by ground traces 42 made using a system in accordance with an embodiment of the present disclosure.

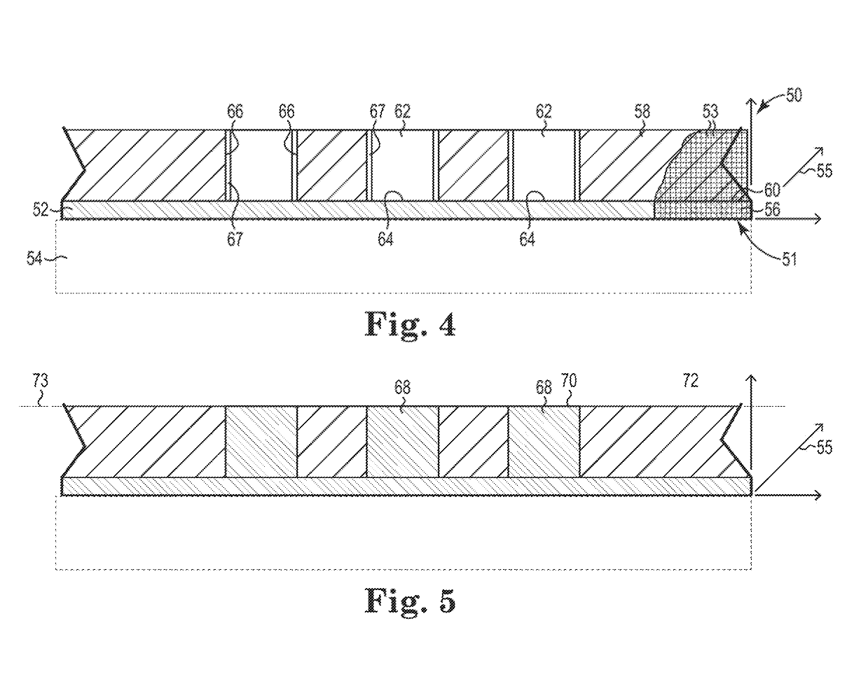

FIG. 4 illustrates one embodiment for replicating circuit structure 50 using the present system to create circuit traces and via structures in accordance with an embodiment of the present disclosure. The resultant construction is an aggregation of cubic positions 53 of various material types arranged in a three-dimensional array 51 relative to a coordinate system 55.

A copper foil 52 is preferably supported by base layer 54. The base layer 54 can be a sacrificial member that is removed at some point later in the process. If the end product is a flexible circuit, the base layer 54 can be a material such as polyimide or liquid crystal polymer. If the final product is a rigid circuit board, the base layer 54 can be FR4 or one of many high speed laminates or substrates. If the final product is a semiconductor package, the base layer 54 can be a material such as FR4, BT resin of any one of a variety of laminate or substrate materials. In the illustrated embodiment, the copper foil 52 can be pre-formed circuitry layer 56 or can be formed using a fine line imaging step to etch copper foil as is done with many PCB processes. The circuitry layer 56 can include fine line etching with spacing between copper traces of about 25 microns.

Dielectric 58 is applied to the designated cubic positions 53 on surface 60 such that the circuitry 56 is at least partially in contact with the dielectric 58. The dielectric layer 58 may be a film or a liquid. The dielectric layer 58 can be applied by screen printing, stencil printing, jetting, flooding, spraying etc. Selected cubic positions 53 on the dielectric material are then imaged to create the recesses or vias 62 that expose the circuit locations 64. Any configuration of cubic positions 53 can be imaged and will result in a grown full metal via 68 of the desired shape. Alternatively, the recesses or vias 62 can be formed using a laser direct imaging process on the selected cubic positions.

In one embodiment, the dielectric 58 is a liquid crystal polymer (“LCP”). Liquid crystal polymers are a class of aromatic polyester polymers that are extremely unreactive and inert so as to be useful for electrical applications. Liquid-crystal polymers are available in melted/liquid or solid form. In solid form the main example of lyotropic LCPs is the commercial aramid known as Kevlar. In a similar way, several series of thermotropic LCPs have been commercially produced by several companies (e.g., Vectran/Ticona). LCP materials have a dielectric constant of about 2.9 at a frequency of about 20 GHz, a co-efficient of thermal expansion of about 8 to about 17 ppm/degree C, and a dimensional stability of less than about 0.1%.

In one embodiment, the core LCP material 58 is processed to enable electro-less copper plating to adhere to the side walls 66 of the recesses 62, such as by using one or more of plasma treatment, permanganate, carbon treatment, impregnating copper nano-particles to activate the surfaces 66 to promote electroplating. The electro-less copper plating applied to the side walls 66 creates conductive structures 67 that are electrically coupled to the circuit layer 56. Additional discussion of the use of electro-less plating of the dielectric structure is disclosed in PCT/US2012/53848, filed Sep. 6, 2012, entitled DIRECT METALIZATION OF ELECTRICAL CIRCUIT STRUCTURES, the entire of disclosure of which is hereby incorporated by reference.

As illustrated in FIG. 5, higher deposition rate electroplate copper can be used to fill the cubic positions 53 corresponding to the recess 62 with bulk copper to grow a full metal, solid copper pillar or via structure 68. The conductivity of the bulk copper pillar 68 is on the order of about 1.68×10⁻⁶ ohm-cm.

In another embodiment, the circuitry layer 56 is used to electroplate the circuit locations 64. The copper plating 68 adheres primarily to the base copper 58 at the locations 64. The dielectric 58 and base layer 54 act as a resist to prevent copper plating any of the positions 53 except in the recesses 62. The resulting copper pillar 68 is preferably a solid copper structure, without voids.

The plating process can be controlled to a certain degree, but in some cases with fine pitch geometries and high speed circuits, the upper surfaces 70 of the copper pillars 68 may vary in topography or height relative to the exposed surface 72 of the dielectric. Also, the dielectric may vary in thickness slightly especially if liquid material is used. The copper pillars 68 are preferably planarized and the thickness of the dielectric controlled between steps if needed to create a controlled dimension and flat reference plane 73 for the subsequent processing steps and layers.

For higher aspect ratio via connections 68, the process can be performed in a number of steps. For example, another layer of LCP 58 can be applied and imaged to expose the upper surfaces 70 of the previous copper pillars 68, with the next plating step increasing the height of the copper pillar 68 incrementally. Planarization is preferably performed between each layer.

FIG. 6 illustrates another embodiment for creating higher aspect ratio via connections. Discrete LCP layer 80 is imaged and plated to create an array of copper pillars 82, as discussed herein. The layer 80 is preferably prepared as a separate matrix 81 of cubic positions 83. The cubic positions 83 are then registered with corresponding cubic positions 53 in the array 51. The lower surfaces 86 of the copper pillars 82 are aligned with the upper surfaces 70 of the copper pillars 68 and the stack 84 is then fusion bonded using heat and pressure 74.

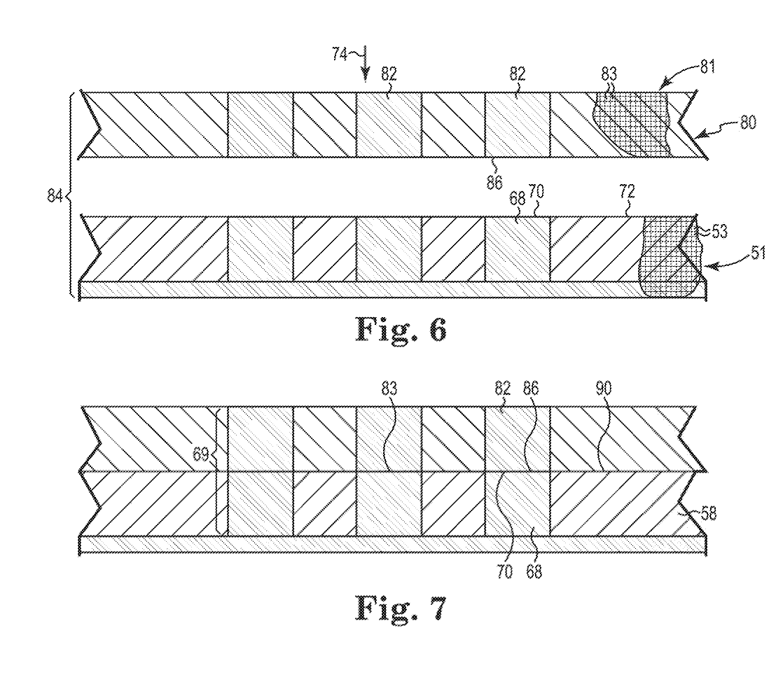

As best illustrated in FIG. 7, upper surfaces 70 of the copper pillars 68 are held in intimate contact with lower surfaces 86 of the copper pillars 82 by the fusion bond 90 of the LCP layers 58, 80. This mechanical connection can be augmented by the addition of a deformable conductive material, such as a conductive paste, located at interface 83 of the surfaces 70, 86.

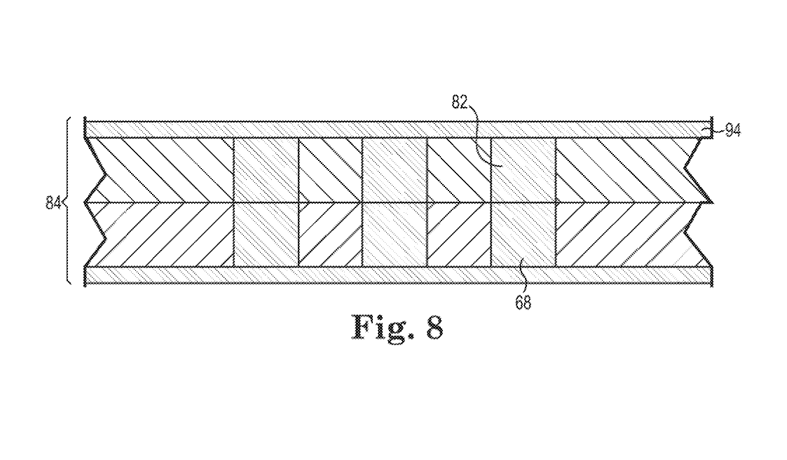

FIG. 8 illustrates an optional copper layer 94 added to create the base for additional routing layers and to facilitate vertical via connection to subsequent layers in the stack 84. The present process creates the ability to stack full metal vias 68, 82 in subsequent deposition steps and/or layers to create a high aspect ratio via without the need to drill through the entire stack in one operation.

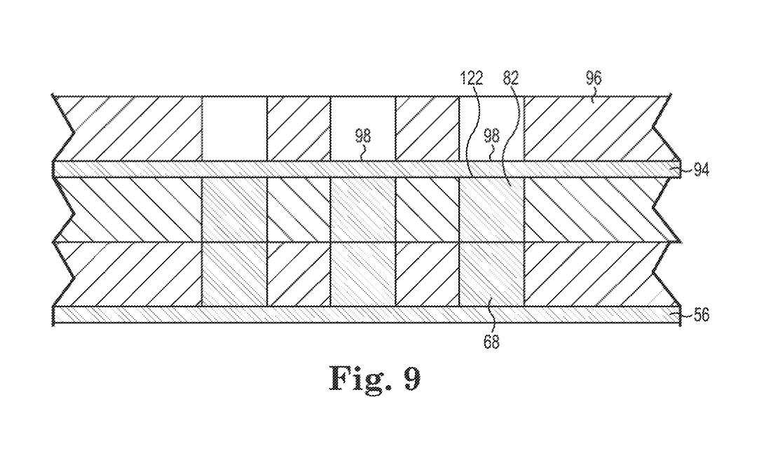

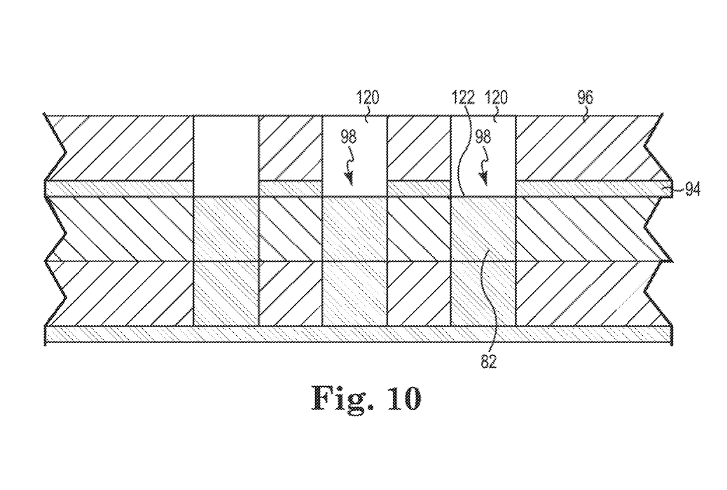

As illustrated in FIG. 9, resist layer 96 can be added to the subsequent copper foil 94 and imaged to expose circuit locations 98. The LCP 96 flows and fills any recessed regions within a previous circuit landscape 94. The present process can also be used in combination with existing dry film techniques. For example, one or more of the layers can be a preformed dielectric film to leave air dielectric gaps between traces in the circuit layer 94.

In the illustrated embodiment, the circuit locations 98 are electrically coupled with the tops surfaces 122 of the pillars 82 and connect to the circuit layer 94. The resist layer 96 protects circuit layers 56, 94 that are not to be etched and provides contact points to the previous pillar 68, 82.

FIG. 10 illustrates a subsequent etch process that removes the copper foil 94 at the cubic positions 53 corresponding to locations 98 in the recesses 120 to provide access to top surfaces 122 of the pillars 82 to allow access for the next plating step to join the layers together in accordance with an alternate embodiment of the present disclosure. Depending on the material 96 and the desired final construction, the layer 96 can be stripped to provide a level to be planarized as the base for subsequent layers or the layer 96 can be left in place.

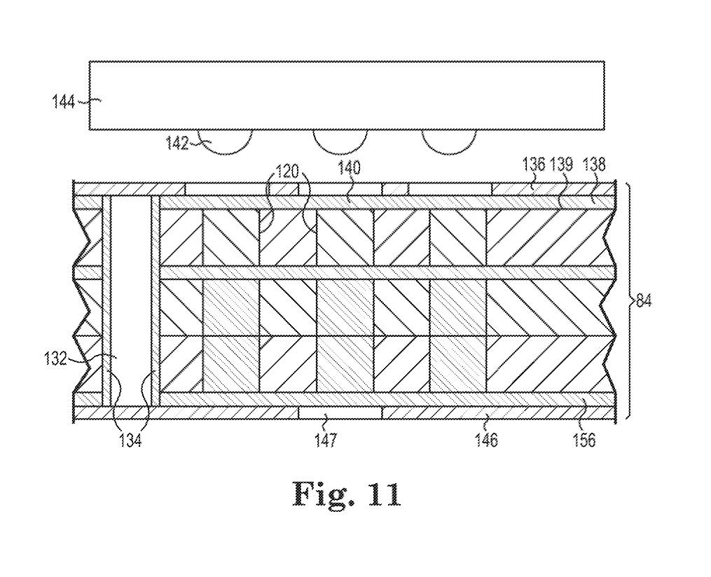

As illustrated in FIG. 11, the cubic positions 53 corresponding to the recesses 120 can optionally be filled with similar LCP material 130, followed by a planarization step. A circuitry layer 138 is then added to the planarized surface 139. The stack 84 can be further processed with conventional circuit fabrication processes to add larger diameter through vias or through holes 132 with optional plating 134 as needed.

A solder mask 136 can be applied on circuitry layer 138 and imaged to expose device termination locations 140. The solder mask 136 can also be laser direct imaging. In one embodiment, the solder mask 136 is a LCP. The locations 140 are configured to correspond to solder balls 142 on BGA device 144. In the illustrated embodiment, bottom dielectric layer 146 is optionally deposited on circuitry layer 56 in a manner to expose selective regions 147.

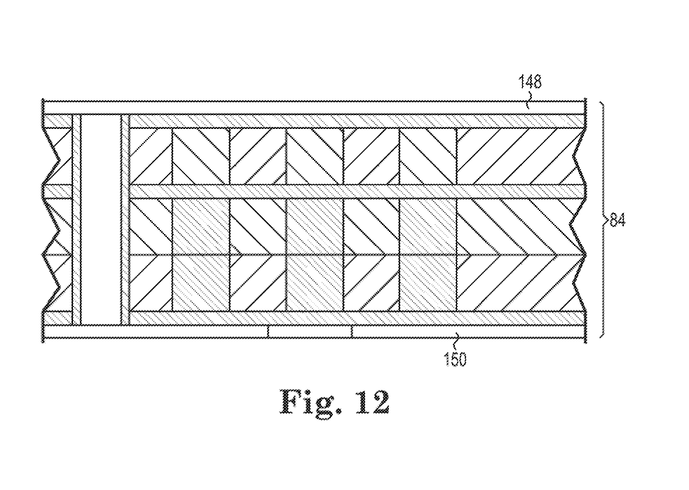

As illustrated in FIG. 12, for flexible circuit applications the stack 84 is laminated with ground planes, cover layers, final finish 148, 150. The laminated layers 148, 150 are preferably represented as separate matrixes combined to the existing matrix 51 (see FIG. 4). In some applications the insulating areas can be applied by jet printing of polyimide or LCP as a final layer or as a combination of laminated film and jetted material.

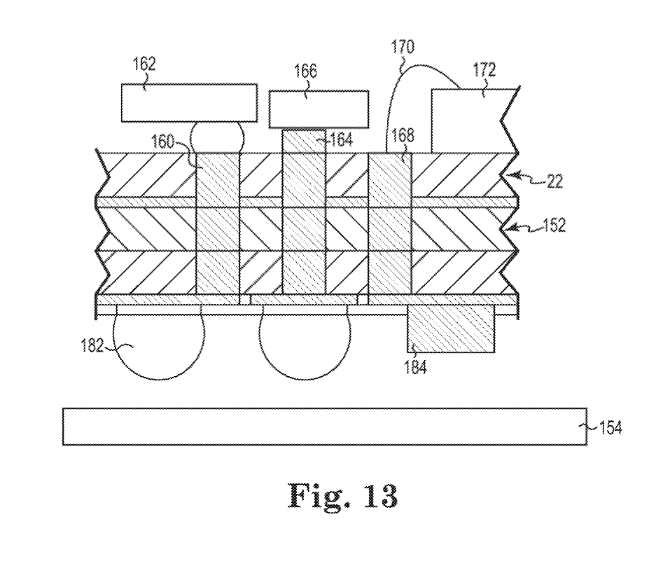

FIG. 13 illustrates an embodiment for semiconductor packaging applications in accordance with an embodiment of the present disclosure. The stack 152 can be final processed with a variety of options to facilitate attachment of dies 162, 166, 172, as well as system level attachment to a PCB 154. The dies 162, 166, 172 are optionally represented as separate matrixes to be added to the matrix 51 or part of the existing matrix 51.

In one embodiment, the pillar 160 is planarized to facilitate flip chip attach to the structure directly (see e.g., FIG. 2) or to receive BGA device 162. In another embodiment, plating 164 is extended to facilitate direct soldering of IC device die 166 with paste. In yet another embodiment, plating 168 is wire bonded 170 to the IC device 172.

On the system interconnect side the structure can be processed to accept a traditional ball grid array attachment 182 for an area array configuration or plated with solder/tin etc. for a no lead peripheral termination. The structure can also be fashioned to have pillar or post extensions 184 to facilitate direct solder attach with paste and to provide a natural standoff.

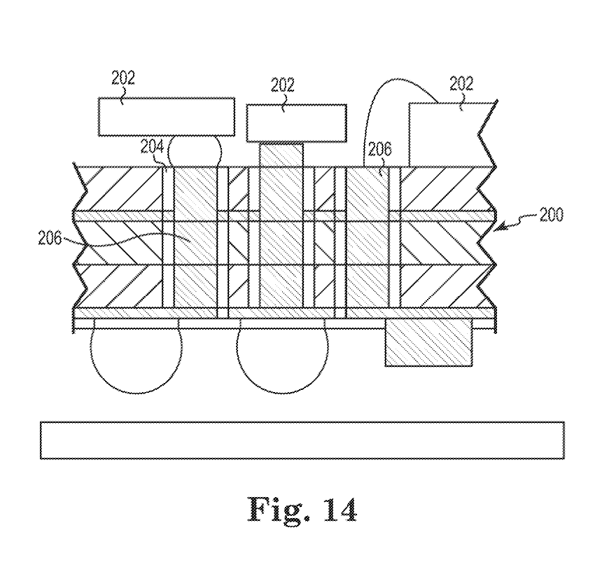

FIG. 14 illustrates an electrical circuit 200 for a semiconductor package 202 with LCP dielectric materials 204 surrounding the vias, internal circuits, terminations, and conductive structures 206 in accordance with an embodiment of the present disclosure. Internal circuits and terminations may also be added by imaging or drilling the core material with a larger opening than needed and filling those openings with an LCP material and imaging the desired geometry to facilitate conductive structure formation.

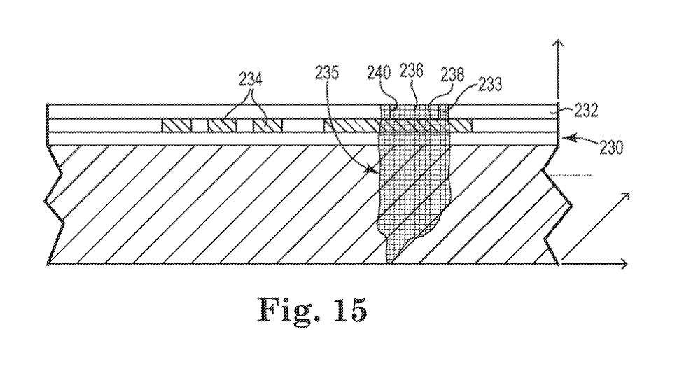

FIG. 15 illustrates an alternate electrical circuit 230 with an insulating layer 232 applied to the circuit geometry 234 constructed within a matrix 235 using the system of the present disclosure. The nature of the liquid dielectric application process allows for selective application of dielectric layer 232 in the desired positions 233 within the matrix 235, while leaving selected positions 236 of the circuit geometry 234 expose if desired. The resulting high density electrical circuit 230 can potentially be considered entirely “green” with limited or no chemistry used to produce beyond the direct write materials.

The dielectric layers of the present disclosure may be constructed of any of a number of dielectric materials that are currently used to make sockets, semiconductor packaging, and printed circuit boards. Examples may include UV stabilized tetrafunctional epoxy resin systems referred to as Flame Retardant 4 (FR-4); bismaleimide-triazine thermoset epoxy resins referred to as BT-Epoxy or BT Resin; and liquid crystal polymers (LCPs), which are polyester polymers that are extremely unreactive, inert and resistant to fire. Other suitable plastics include phenolics, polyesters, and Ryton® available from Phillips Petroleum Company.

In one embodiment, one or more of the dielectric materials are designed to provide electrostatic dissipation or to reduce cross-talk between the traces of the circuit geometry. An efficient way to prevent electrostatic discharge (“ESD”) is to construct one of the layers from materials that are not too conductive but that will slowly conduct static charges away. These materials preferably have resistivity values in the range of 10⁵ to 10¹¹ Ohm-meters.

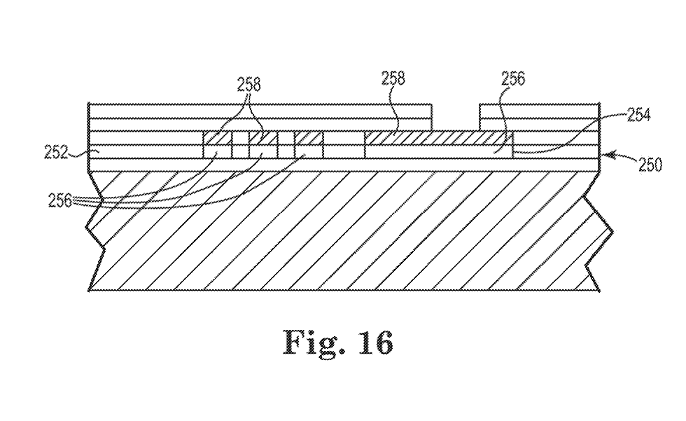

FIG. 16 illustrates an alternate high density electrical circuit 250 in accordance with an embodiment of the present disclosure. Dielectric layer 252 includes openings 254 into which compliant material 256 is deposited or printed before formation of circuit geometry 258. The compliant material 256 improves reliability during flexure of the electrical circuit 250.

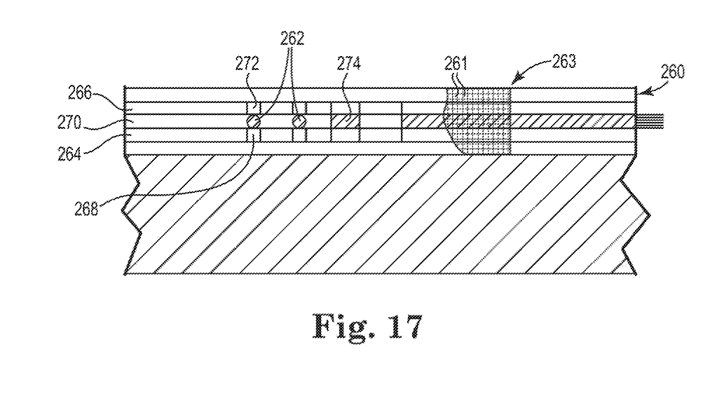

FIG. 17 illustrates an alternate high performance electrical circuit 260 in accordance with an embodiment of the present disclosure. The dielectric layer 270 is imaged to create recesses at the desired cubic positions 261 within matrix 263 to receive pre-formed optical fibers 262. In another embodiment, the optical fibers 262 are located between layers 264, 266 of dielectric material. In one embodiment, optical fibers 262 are positioned over compliant layer 268, and dielectric layer 270 is formed over and around the optical fibers 262. A compliant layer 272 is preferably provided above the optical fiber 262 as well. The compliant layers 268, 272 support the optical fibers 262 during flexure.

In another embodiment, optical quality materials 274 are printed in the desire cubic positions 261 during assembly of the high density electrical circuit 260. The optical quality material 274 and/or the optical fibers 262 comprise optical circuit geometries. The printing process allows for deposition of coatings in-situ that enhances the optical transmission or reduces loss. The precision of the printing process reduces misalignment issues when the optical materials 274 are optically coupled with another optical structure.

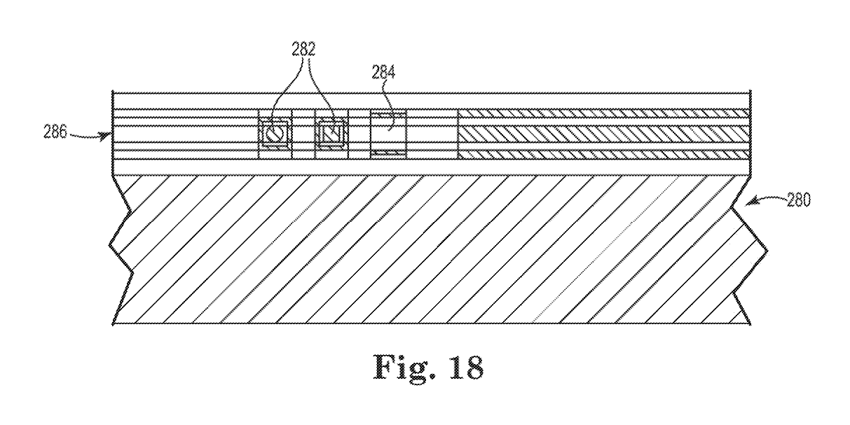

FIG. 18 illustrates another embodiment of a present high density electrical circuit 280 in accordance with an embodiment of the present disclosure. Embedded coaxial RF circuits 282 or printed micro strip RF circuits 284 are located within the dielectric layers 286. These RF circuits 282, 284 are preferably created by printing dielectrics and metallization geometry.

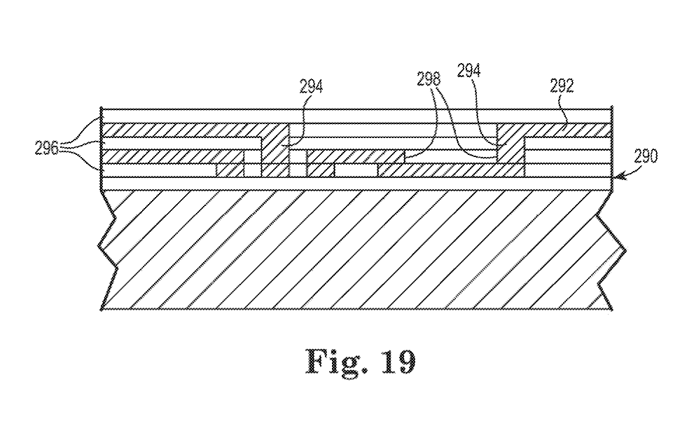

As illustrated in FIG. 19, use of the present process allows the creation of a high density electrical circuit 290 with inter-circuit, 3D lattice structures 292 having intricate routing schemes. Conductive pillars 294 can be plated with each layer, without drilling.

The nature of the present process permit controlled application of dielectric layers 296 creates recesses 298 that control the location, cross section, material content, and aspect ratio of the conductive traces 292 and the conductive pillars 294. Maintaining the conductive traces 292 and conductive pillars 294 with a cross-section of 1:1 or greater provides greater signal integrity than traditional subtractive trace forming technologies. For example, traditional methods take a sheet of a given thickness and etches the material between the traces away to have a resultant trace that is usually wider than it is thick. The etching process also removes more material at the top surface of the trace than at the bottom, leaving a trace with a trapezoidal cross-sectional shape, degrading signal integrity in some applications.

Using the imaged recesses 298 to control the aspect ratio of the conductive traces 292 and the conductive pillars 294 results in a more rectangular or square cross-section, with the corresponding improvement in signal integrity. The recesses 298 are preferably processed to receive electro-less plating, followed by electroplating to build up the conductive traces 292.

In another embodiment, pre-patterned or pre-etched thin conductive foil circuit traces are transferred to the recesses 298. For example, a pressure sensitive adhesive can be used to retain the copper foil circuit traces in the recesses 298. The trapezoidal cross-sections of the pre-formed conductive foil traces are then post-plated. The plating material fills the open spaces in the recesses 298 not occupied by the foil circuit geometry, resulting in a substantially rectangular or square cross-sectional shape corresponding to the shape of the recesses 298.

In another embodiment, a thin conductive foil is pressed into the recesses 298, and the edges of the recesses 298 acts to cut or shear the conductive foil. The process locates a portion of the conductive foil in the recesses 298, but leaves the negative pattern of the conductive foil not wanted outside and above the recesses 298 for easy removal. Again, the foil in the recesses 298 is preferably post plated to add material to increase the thickness of the conductive traces 292 in the circuit geometry and to fill any voids left between the conductive foil and the recesses 298.

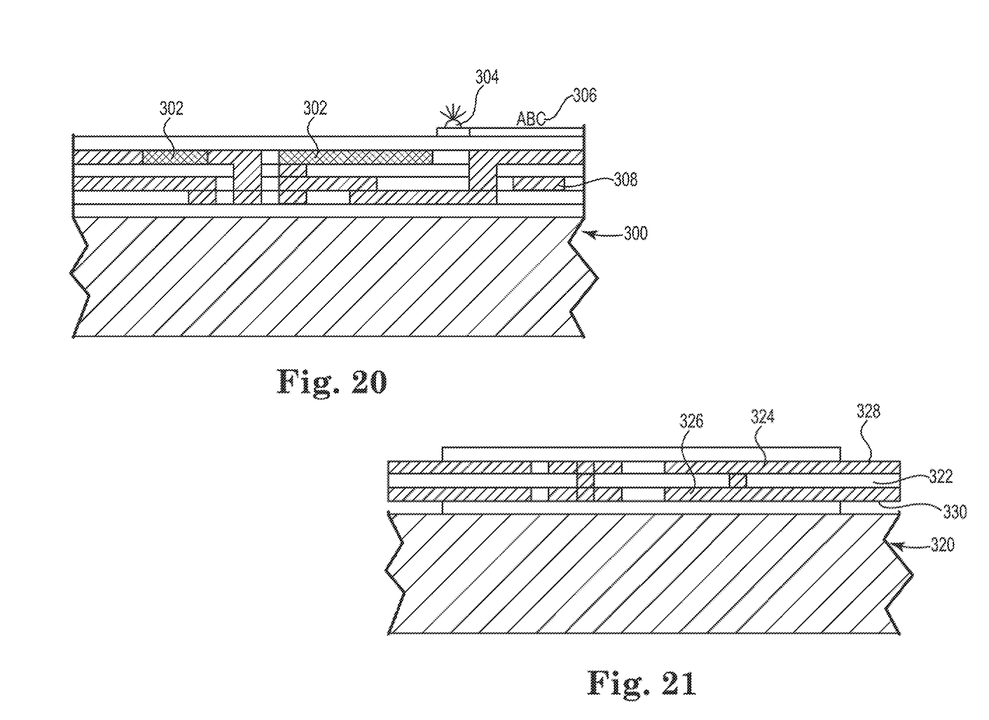

FIG. 20 illustrates a high density electrical circuit 300 with printed electrical devices 302. The electrical devices 302 can include passive or active functional elements. Passive structure refers to a structure having a desired electrical, magnetic, or other property, including but not limited to a conductor, resistor, capacitor, inductor, insulator, dielectric, suppressor, filter, varistor, ferromagnet, and the like. In the illustrated embodiment, electrical devices 302 include printed LED indicator 304 and display electronics 306. Geometries can also be printed to provide capacitive coupling 308. Compliant material can be added between circuit geometry, such as discussed above, so the present electrical circuit can be plugged into a receptacle or socket, supplementing or replacing the need for compliance within the connector.

The electrical devices 302 are preferably printed during construction of the circuit assembly 300. The electrical devices 302 can be ground planes, power planes, electrical connections to other circuit members, dielectric layers, conductive traces, transistors, capacitors, resistors, RF antennae, shielding, filters, signal or power altering and enhancing devices, memory devices, embedded IC, and the like. For example, the electrical devices 302 can be formed using printing technology, adding intelligence to the high performance electrical circuit 300. Features that are typically located on other circuit members can be incorporated into the circuit 300 in accordance with an embodiment of the present disclosure.

The availability of printable silicon inks provides the ability to print electrical devices 302, such as disclosed in U.S. Pat. No. 7,485,345 (Renn et al.); U.S. Pat. No. 7,382,363 (Albert et al.); U.S. Pat. No. 7,148,128 (Jacobson); U.S. Pat. No. 6,967,640 (Albert et al.); U.S. Pat. No. 6,825,829 (Albert et al.); U.S. Pat. No. 6,750,473 (Amundson et al.); U.S. Pat. No. 6,652,075 (Jacobson); U.S. Pat. No. 6,639,578 (Comiskey et al.); U.S. Pat. No. 6,545,291 (Amundson et al.); U.S. Pat. No. 6,521,489 (Duthaler et al.); U.S. Pat. No. 6,459,418 (Comiskey et al.); U.S. Pat. No. 6,422,687 (Jacobson); U.S. Pat. No. 6,413,790 (Duthaler et al.); U.S. Pat. No. 6,312,971 (Amundson et al.); U.S. Pat. No. 6,252,564 (Albert et al.); U.S. Pat. No. 6,177,921 (Comiskey et al.); U.S. Pat. No. 6,120,588 (Jacobson); U.S. Pat. No. 6,118,426 (Albert et al.); and U.S. Pat. Publication No. 2008/0008822 (Kowalski et al.), which are hereby incorporated by reference. In particular, U.S. Pat. No. 6,506,438 (Duthaler et al.) and U.S. Pat. No. 6,750,473 (Amundson et al.), which are incorporated by reference, teach using ink-jet printing to make various electrical devices, such as, resistors, capacitors, diodes, inductors (or elements which may be used in radio applications or magnetic or electric field transmission of power or data), semiconductor logic elements, electro-optical elements, transistor (including, light emitting, light sensing or solar cell elements, field effect transistor, top gate structures), and the like.

The electrical devices 302 can also be created by aerosol printing, such as disclosed in U.S. Pat. No. 7,674,671 (Renn et al.); U.S. Pat. No. 7,658,163 (Renn et al.); U.S. Pat. No. 7,485,345 (Renn et al.); U.S. Pat. No. 7,045,015 (Renn et al.); and U.S. Pat. No. 6,823,124 (Renn et al.), which are hereby incorporated by reference.

Printing processes are preferably used to fabricate various functional structures, such as conductive paths and electrical devices, without the use of masks or resists. Features down to about 10 microns can be directly written in a wide variety of functional inks, including metals, ceramics, polymers and adhesives, on virtually any substrate—silicon, glass, polymers, metals and ceramics. The substrates can be planar and non-planar surfaces. The printing process is typically followed by a thermal treatment, such as in a furnace or with a laser, to achieve dense functionalized structures.

Ink jet printing of electronically active inks can be done on a large class of substrates, without the requirements of standard vacuum processing or etching. The inks may incorporate mechanical, electrical or other properties, such as, conducting, insulating, resistive, magnetic, semi conductive, light modulating, piezoelectric, spin, optoelectronic, thermoelectric or radio frequency.

A plurality of ink drops are dispensed from the print head directly to a substrate or on an intermediate transfer member. The transfer member can be a planar or non-planar structure, such as a drum. The surface of the transfer member can be coated with a non-sticking layer, such as silicone, silicone rubber, or Teflon.

The ink (also referred to as function inks) can include conductive materials, semi-conductive materials (e.g., p-type and n-type semiconducting materials), metallic material, insulating materials, and/or release materials. The ink pattern can be deposited in precise locations on a substrate to create fine lines having a width smaller than 10 microns, with precisely controlled spaces between the lines. For example, the ink drops form an ink pattern corresponding to portions of a transistor, such as a source electrode, a drain electrode, a dielectric layer, a semiconductor layer, or a gate electrode.

The substrate can be an insulating polymer, such as polyethylene terephthalate (PET), polyester, polyethersulphone (PES), polyimide film (e.g. Kapton, available from DuPont located in Wilmington, Del.; Upilex available from Ube Corporation located in Japan), or polycarbonate. Alternatively, the substrate can be made of an insulator such as undoped silicon, glass, or a plastic material. The substrate can also be patterned to serve as an electrode. The substrate can further be a metal foil insulated from the gate electrode by a non-conducting material. The substrate can also be a woven material or paper, planarized or otherwise modified on at least one surface by a polymeric or other coating to accept the other structures.

Electrodes can be printed with metals, such as aluminum or gold, or conductive polymers, such as polythiophene or polyaniline. The electrodes may also include a printed conductor, such as a polymer film comprising metal particles, such as silver or nickel, a printed conductor comprising a polymer film containing graphite or some other conductive carbon material, or a conductive oxide such as tin oxide or indium tin oxide.

Dielectric layers can be printed with a silicon dioxide layer, an insulating polymer, such as polyimide and its derivatives, poly-vinyl phenol, polymethylmethacrylate, polyvinyldenedifluoride, an inorganic oxide, such as metal oxide, an inorganic nitride such as silicon nitride, or an inorganic/organic composite material such as an organic-substituted silicon oxide, or a sol-gel organosilicon glass. Dielectric layers can also include a bicylcobutene derivative (BCB) available from Dow Chemical (Midland, Mich.), spin-on glass, or dispersions of dielectric colloid materials in a binder or solvent.

Semiconductor layers can be printed with polymeric semiconductors, such as, polythiophene, poly(3-alkyl)thiophenes, alkyl-substituted oligothiophene, polythienylenevinylene, poly(para-phenylenevinylene) and doped versions of these polymers. An example of suitable oligomeric semiconductor is alpha-hexathienylene. Horowitz, Organic Field-Effect Transistors, Adv. Mater., 10, No. 5, p. 365 (1998) describes the use of unsubstituted and alkyl-substituted oligothiophenes in transistors. A field effect transistor made with regioregular poly(3-hexylthiophene) as the semiconductor layer is described in Bao et al., Soluble and Processable Regioregular Poly(3-hexylthiophene) for Thin Film Field-Effect Transistor Applications with High Mobility, Appl. Phys. Lett. 69 (26), p. 4108 (December 1996). A field effect transistor made with a-hexathienylene is described in U.S. Pat. No. 5,659,181, which is incorporated herein by reference.

A protective layer can optionally be printed onto the electrical devices. The protective layer can be an aluminum film, a metal oxide coating, a polymeric film, or a combination thereof.

Organic semiconductors can be printed using suitable carbon-based compounds, such as, pentacene, phthalocyanine, benzodithiophene, buckminsterfullerene or other fullerene derivatives, tetracyanonaphthoquinone, and tetrakisimethylanimoethylene. The materials provided above for forming the substrate, the dielectric layer, the electrodes, or the semiconductor layer are exemplary only. Other suitable materials known to those skilled in the art having properties similar to those described above can be used in accordance with the present disclosure.

The ink-jet print head preferably includes a plurality of orifices for dispensing one or more fluids onto a desired media, such as for example, a conducting fluid solution, a semiconducting fluid solution, an insulating fluid solution, and a precursor material to facilitate subsequent deposition. The precursor material can be surface active agents, such as octadecyltrichlorosilane (OTS).

Alternatively, a separate print head is used for each fluid solution. The print head nozzles can be held at different potentials to aid in atomization and imparting a charge to the droplets, such as disclosed in U.S. Pat. No. 7,148,128 (Jacobson), which is hereby incorporated by reference. Alternate print heads are disclosed in U.S. Pat. No. 6,626,526 (Ueki et al.), and U.S. Pat. Publication Nos. 2006/0044357 (Andersen et al.) and 2009/0061089 (King et al.), which are hereby incorporated by reference.

The print head preferably uses a pulse-on-demand method, and can employ one of the following methods to dispense the ink drops: piezoelectric, magnetostrictive, electromechanical, electro pneumatic, electrostatic, rapid ink heating, magneto hydrodynamic, or any other technique well known to those skilled in the art. The deposited ink patterns typically undergo a curing step or another processing step before subsequent layers are applied.

While ink jet printing is preferred, the term “printing” is intended to include all forms of printing and coating, including: pre-metered coating such as patch die coating, slot or extrusion coating, slide or cascade coating, and curtain coating; roll coating such as knife over roll coating, forward and reverse roll coating; gravure coating; dip coating; spray coating; meniscus coating; spin coating; brush coating; air knife coating; screen printing processes; electrostatic printing processes; thermal printing processes; and other similar techniques.

FIG. 21 illustrates an alternate high density electrical circuit 320 with compliant material 322 added between circuit geometries 324, 326 to facilitate insertion of circuit geometries 328, 330 into a receptacle or socket. The compliant material 322 can supplement or replace the compliance in the receptacle or socket. In one embodiment, the compliance is provided by a combination of the compliant material 322 and the exposed circuit geometries 328, 330.

Where a range of values is provided, it is understood that each intervening value, to the tenth of the unit of the lower limit unless the context clearly dictates otherwise, between the upper and lower limit of that range and any other stated or intervening value in that stated range is encompassed within the embodiments of the disclosure. The upper and lower limits of these smaller ranges which may independently be included in the smaller ranges is also encompassed within the embodiments of the disclosure, subject to any specifically excluded limit in the stated range. Where the stated range includes one or both of the limits, ranges excluding either both of those included limits are also included in the embodiments of the present disclosure.

Unless defined otherwise, all technical and scientific terms used herein have the same meaning as commonly understood by one of ordinary skill in the art to which the embodiments of the present disclosure belong. Although any methods and materials similar or equivalent to those described herein can also be used in the practice or testing of the embodiments of the present disclosure, the preferred methods and materials are now described. All patents and publications mentioned herein, including those cited in the Background of the application, are hereby incorporated by reference to disclose and described the methods and/or materials in connection with which the publications are cited.

The publications discussed herein are provided solely for their disclosure prior to the filing date of the present application. Nothing herein is to be construed as an admission that the present disclosure is not entitled to antedate such publication by virtue of prior invention. Further, the dates of publication provided may be different from the actual publication dates which may need to be independently confirmed.

Other embodiments of the disclosure are possible. Although the description above contains much specificity, these should not be construed as limiting the scope of the disclosure, but as merely providing illustrations of some of the presently preferred embodiments of this disclosure. It is also contemplated that various combinations or sub-combinations of the specific features and aspects of the embodiments may be made and still fall within the scope of the present disclosure. It should be understood that various features and aspects of the disclosed embodiments can be combined with or substituted for one another in order to form varying modes of the disclosed embodiments of the disclosure. Thus, it is intended that the scope of the present disclosure herein disclosed should not be limited by the particular disclosed embodiments described above.

Thus the scope of this disclosure should be determined by the appended claims and their legal equivalents. Therefore, it will be appreciated that the scope of the present disclosure fully encompasses other embodiments which may become obvious to those skilled in the art, and that the scope of the present disclosure is accordingly to be limited by nothing other than the appended claims, in which reference to an element in the singular is not intended to mean “one and only one” unless explicitly so stated, but rather “one or more.” All structural, chemical, and functional equivalents to the elements of the above-described preferred embodiment(s) that are known to those of ordinary skill in the art are expressly incorporated herein by reference and are intended to be encompassed by the present claims. Moreover, it is not necessary for a device or method to address each and every problem sought to be solved by the present disclosure, for it to be encompassed by the present claims. Furthermore, no element, component, or method step in the present disclosure is intended to be dedicated to the public regardless of whether the element, component, or method step is explicitly recited in the claims.

What is claimed is:

1. A method of making a circuit structure comprising the steps of:
creating a first three dimensional matrix divided into a plurality of uniformly sized cubic positions;
defining a series of steps for making a first circuit structure including for each cubic position at least position data locating the cubic position within the first three dimensional matrix and a material for each cubic position;
allocating at designated cubic positions within the first matrix a first dielectric layer, the first dielectric layer including a plurality of cubic positions comprising recesses corresponding to a target circuit geometry;
depositing a conductive material in at least a portion of the cubic positions corresponding to the recesses to form a circuit geometric comprising a plurality of conductive traces; and
allocating at designated cubic positions within the first matrix a second dielectric layer extending over at least a portion of the cubic positions containing the conductive material.

2. The method of claim 1 wherein the materials are selected from one of conductive, non-conductive, or semi-conductive materials, compliant materials, or air.

3. The method of claim 1 comprising printing the dielectric material on a substrate located in the first matrix, wherein the substrate comprises one of a polymeric film or a dielectric substrate.

4. The method of claim 1 comprising the steps of:
processing the cubic positions corresponding to the recesses to receive electro-less plating; and
electro-less plating the processed cubic position.

5. The method of claim 4 comprising the steps of:
applying a plating resist to selected cubic positions adjacent to the electro-less plated cubic positions;
substantially filling the electro-less plated cubic position with a conductive material using electro-deposit plating; and
removing the plating resist.

6. The method of claim 1 comprising the steps of:
arranging the cubic positions corresponding to the recesses to form a plurality of contact members; and
depositing a conductive material in the designated cubic positions.

7. The method of claim 6 comprising locating a compliant material in cubic positions adjacent to the contact members.

8. The method of claim 1 wherein the step of depositing the conductive material in at least a portion of the cubic positions forms at least one of a via or a contact member.

9. The method of claim 1 comprising the steps of:
designating a plurality of cubic positions in the first dielectric layer for an electrical device;
printing an electrical device in the designated cubic positions; and
electrically coupling the electrical device to the circuit geometry.

10. The method of claim 1 comprising the steps of:
creating a second three dimensional matrix divided into a plurality of uniformly sized cubic positions;
defining a series of steps for making a second circuit structure; and
bonding the first circuit structure to the second circuit structure.
